(19) United States
(12) Patent Application Publication
(10) Pub. No.: US 2013/0250526 A1
(43) Pub. Date: Sep. 26, 2013

(54) ELECTRONIC DEVICE WITH CABLE SECURING MECHANISM

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventors: PING LI, Shenzhen (CN); XUE-FENG WAN, Shenzhen (CN)

(73) Assignees: HON HAI PRECISION INDUSTRY CO., LTD., New Taipei (TW); HONG FU JIN PRECISION INDUSTRY (ShenZhen) CO., LTD, Shenzhen (CN)

(21) Appl. No.: 13/776,742

(22) Filed: Feb. 26, 2013

(30) Foreign Application Priority Data
Mar. 23, 2012 (CN) 201210078863.1

(51) Int. Cl. H05K 7/02

(52) U.S. Cl. CPC H05K 7/02
USPC 361/748

(57) ABSTRACT

An electronic device includes a front cover, a rear cover coupled to the front cover, a circuit board fixed to the front cover, a connector mounted on the circuit board, and a cable including a first end connected to the connector and an opposite, second end. The front cover defines a receiving groove. A bottom of the receiving groove defines a through opening and a restriction element protruding from the bottom of the receiving groove. A smallest distance between a sidewall of the receiving groove and the restriction element is smaller than a diameter of the cable. The second end of the cable passes through the through opening from an inner side of the front cover, and the cable is retainably received in a space between the sidewall and the restriction element.

### BACKGROUND

1. Technical Field

The present disclosure relates to an electronic device with a cable securing mechanism.

2. Description of Related Art

Many electronic devices, digital video disc (DVD) players, for example, include one or more connectors for electrical connection. During the assembly of the electronic device, the operator inserts one end of the cable into the jack of the connector, and then layouts the cable with a tension force according to need. However, the end of the cable inserted into the jack of the connector may be loosen from the jack, and what is worse, may be broken, since the tension force applied on the cable is hard to handle, which brings problems during the assembly. The operator may need to re-assemble the end of the cable to the connector, and the efficiency of the assembly is decreased. For what is worse, the reliability of the connector lowers when the disentanglement of the cable is not noticed in time.

Therefore, what is needed is an electronic device with a cable securing mechanism to overcome the limitations described above.

### BRIEF DESCRIPTION OF THE DRAWINGS

The components in the drawings are not necessarily drawn to scale, the emphasis instead being placed upon clearly illustrating the principles of this disclosure. Moreover, in the drawings, like reference numerals designate corresponding parts throughout the several views.

FIG. 1 is an isometric view of an exemplary embodiment of an electronic device.

FIG. 2 is an exploded view of the electronic device of FIG. 1.

FIG. 3 is similar to FIG. 2, but viewed from another perspective.

FIG. 4 is an isometric view of the electronic device of FIG. 1, with a groove cover of a front cover and a cable omitted for clarity.

FIG. 5 is an isometric view of the electronic device of FIG. 1, with a groove cover of a front cover omitted for clarity.

### DETAILED DESCRIPTION

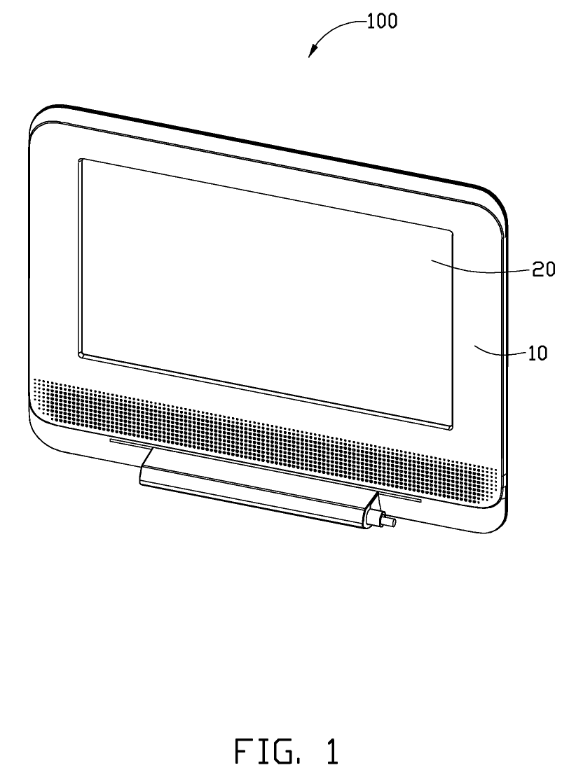

FIGS. 1-3 show an exemplary electronic device 100 of the disclosure. The electronic device 100 includes a housing 10, a display panel 20 fixed in the housing 10, a circuit board 30, a connector 40 fixed on the circuit board 30, and a cable 50 with one end connected to the connector 40 via a connection terminal 51. The housing 10 includes a cable securing mechanism for preventing the cable 50 from disengaging from the connector 40. In the embodiment, the electronic device 100 is a DVD player. In other embodiments, the electronic device 100 can be a mobile phone, a tablet computer, a music player, or other electronic devices with cables that connect to connectors. The display panel 20 is a liquid crystal display (LCD) panel.

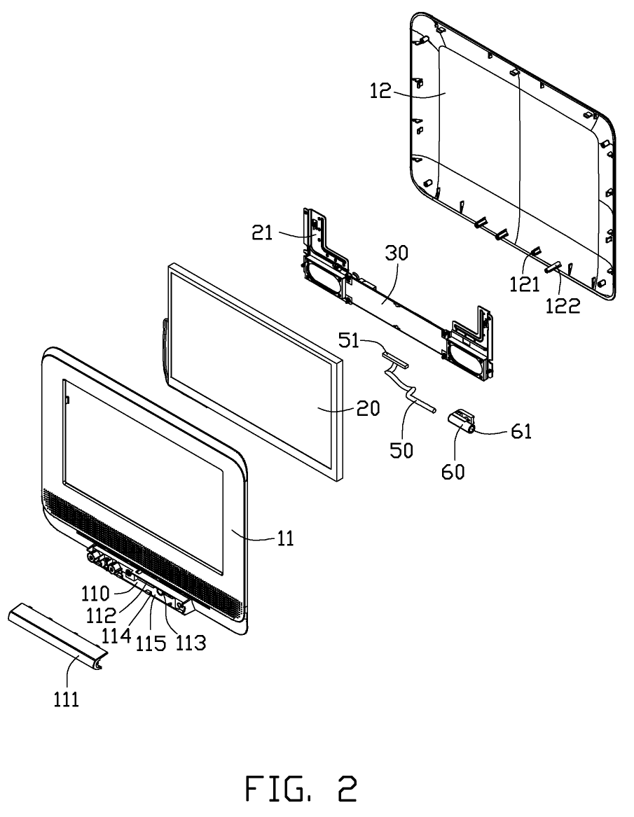

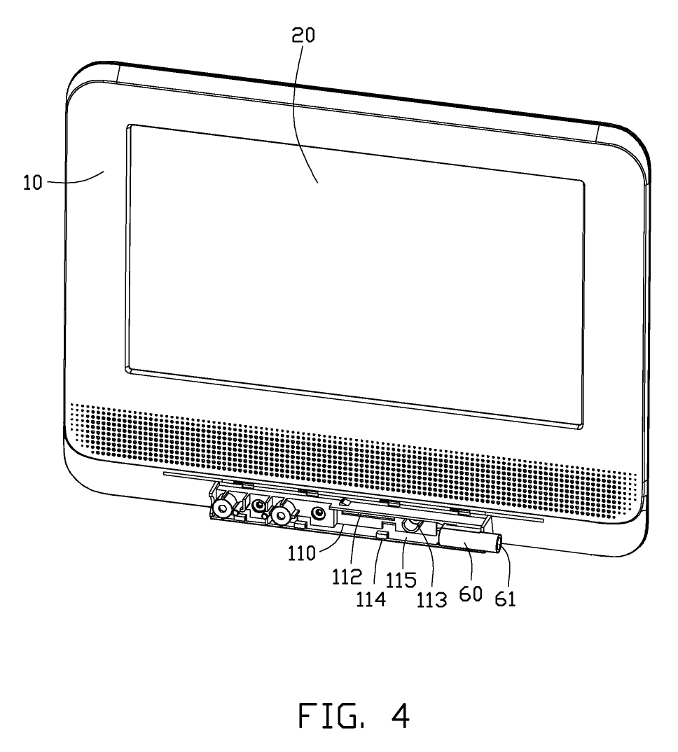

FIGS. 2 and 4 show that the housing 10 includes a front cover 11 and a rear cover 12 coupled to the front cover 11. A first post 121 and a second post 122 protrude from the inner surface of the rear cover 12. In the embodiment, the length of the first post 121 is smaller than the length of the second post 122.

The outer surface of the front cover 11 defines a receiving groove 110 and a groove cover 111 is detachably coupled to the front cover 11 to cover the receiving groove 110. The bottom of the receiving groove 110 defines an opening 112 for the cable 50 to pass therethrough. A restriction element 113 protrudes from the bottom of the receiving groove 110. The restriction element 113 and a sidewall 114 of the receiving groove 110 cooperatively define a space 115 for retainably receiving the cable 50. In the embodiment, the restriction element 113 is a hollow semi-cylinder sleeved on the first post 121. The smallest distance between the sidewall 114 of the receiving groove 110 and the restriction element 113 is slightly smaller than the diameter of the cable 50. As such, the cable 50 is held firmly in position between the sidewall 114 and the restriction element 113. In an alternative embodiment, the shape of the restriction element 113 can be varied, as long as the smallest distance between the sidewall 114 and the restriction element 113 is smaller than the diameter of the cable 50, such that the cable 50 can be pressed into the space 115.

In the embodiment, the restriction element 113, the receiving groove 110 and its sidewall 114 forms a cable securing mechanism of the electronic device 100, for securing the cable 50 to prevent the cable 50 from disengaging from the connector 40.

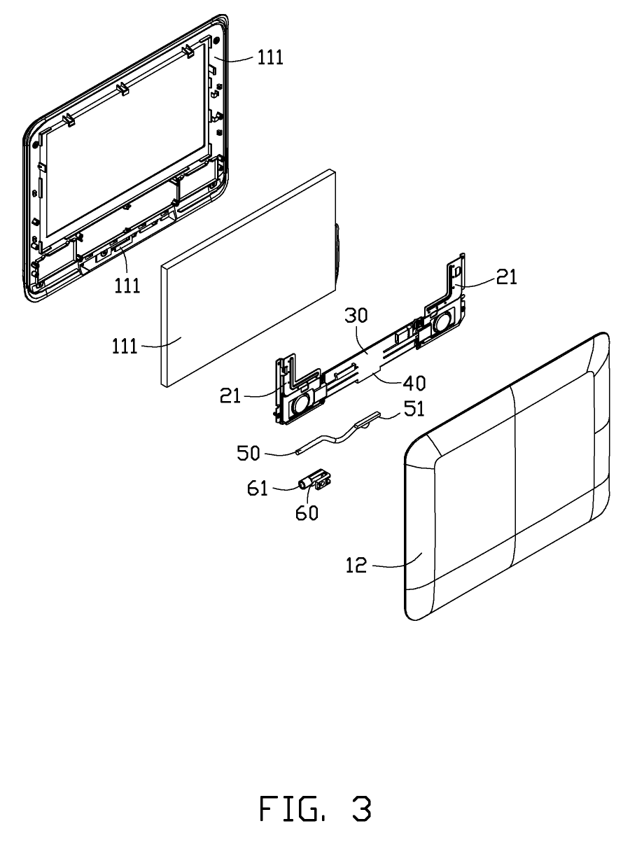

Referring to FIGS. 2 and 3, the electronic device 100 further includes a panel fixing mechanism 21 for fixing the LCD panel 20 in the inner surface of the front cover 11. In the embodiment, the panel fixing mechanisms 21 are a couple of symmetrical fixing mechanisms positioned corresponding to the lower left and lower right of the circuit board 30. The couple of symmetrical fixing mechanisms 21 are fixed to the circuit board 30 via screws (not shown). The circuit board 30 is then fixed to the inner surface of the front cover 11 via screws, thus to fix the LCD panel 20 on the inner surface of the front cover 11.

FIGS. 3-5 show that the electronic device 100 further includes a guiding element 60 fixed to the second post 122 and partially received in the receiving groove 110. The guiding element 60 defines a circular through hole 61 for the cable 50 to pass through. The guiding element 60 is used for guiding the direction of the cable 50, and further helping to prevent the cable 50 from disengaging from the connector 40.

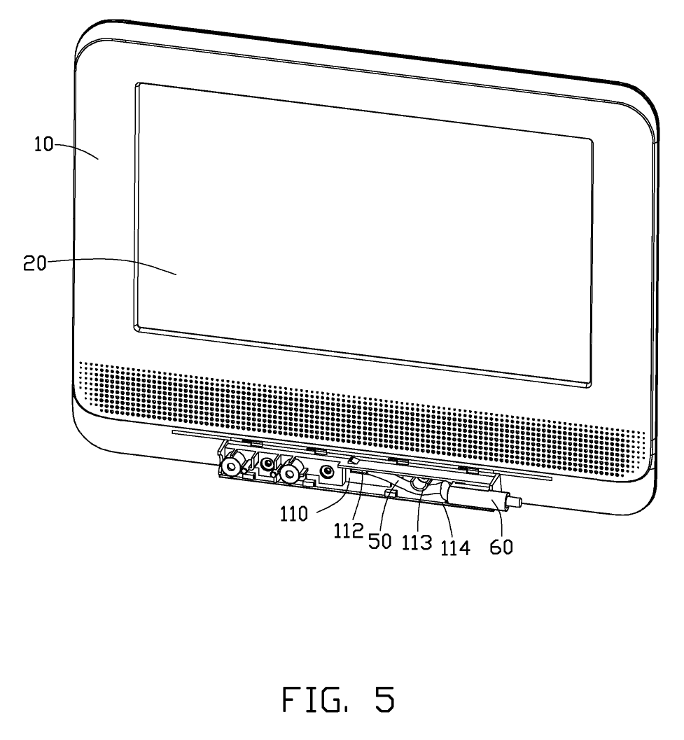

In assembly, the connection terminal 51 of the cable 50 is inserted into the connector 40, and the other, free end (the end away from the connection terminal 51) of the cable 50 is caused to pass through the opening 112 from the inner side of the front cover 11. The cable 50 is then pressed into the space 115 between the sidewall 114 of the receiving groove 110 and the restriction element 113. The free end of the cable 50 is caused to pass through the through hole 61 of the guiding element 60, and connected to another component of the electronic device 100. Referring to FIG. 5, the cable 50 is partially clasped in the space 115, and is partially received in the through hole 61, thus, there is no need to worry about the tension force applied on the cable 50 during the assembly, which improves the efficiency of assembly and saves the production expense.

Although the present disclosure has been specifically described on the basis of the embodiments thereof, the disclosure is not to be construed as being limited thereto. Various changes or modifications may be made to the embodiments without departing from the scope and spirit of the disclosure.

What is claimed is:

1. An electronic device comprising:
a front cover defining a receiving groove, a bottom of the receiving groove defining a through opening and a restriction element protruding from the bottom of the receiving groove;
a circuit board fixed to the front cover;
a connector mounted on the circuit board; and
a cable comprising a first end connected to the connector, and an opposite, second end;
wherein a smallest distance between a sidewall of the receiving groove and the restriction element is smaller than a diameter of the cable, the second end of the cable passes through the through opening from an inner side of the front cover, and the cable is retainably received in a space between the sidewall and the restriction element.

2. The electronic device as described in claim 1, wherein the restriction element is a hollow semi-cylinder.

3. The electronic device as described in claim 2, wherein the electronic device further comprises a rear cover coupled to the front cover, a first post protrudes from the rear cover and is aligned with the restriction element, and the restriction element is sleeved on the first post.

4. The electronic device as described in claim 3, further comprising a guiding element partially received in the receiving groove, and a second post protruding from an inner surface of the rear cover, wherein the guiding element is fixed on the second post.

5. The electronic device as described in claim 1, further comprising a rear cover coupled to the front cover, wherein a first post protrudes from the rear cover and is aligned with the restriction element, and the restriction element is sleeved on the first post.

6. The electronic device as described in claim 1, further comprising a guiding element partially received in the receiving groove, a second post protrudes from an inner surface of the rear cover, and the guiding element is fixed on the second post.
